(19) United States
(12) Patent Application Publication
(10) Pub. No.: US 2023/0313029 A1
(43) Pub. Date: Oct. 5, 2023

(54) LIGHT EMITTING ELEMENT, QUANTUM DOT-CONTAINING COMPOSITION, AND LIGHT EMITTING ELEMENT MANUFACTURING METHOD

(71) Applicant: SHARP KABUSHIKI KAISHA, Sakai City, Osaka (JP)

(72) Inventor: Yukio TAKENAKA, Sakai City, Osaka (JP)

(21) Appl. No.: 18/025,356

(22) PCT Filed: Aug. 17, 2021
(86) PCT No.: PCT/JP2021/029962

§ 371 Date: Mar. 8, 2023

(30) Foreign Application Priority Data
Sep. 18, 2020 (JP) 2020-157235

(51) Int. Cl. C09K 11/02; H10K 50/115

(52) U.S. Cl. CPC C09K 11/025; H10K 50/115; B82Y 20/00

(57) ABSTRACT

A light-emitting element includes a light-emitting layer including the following: a quantum dot including a core and a shell covering the core; and a perovskite compound covering the quantum dot, wherein the shell includes a semiconductor or an insulator containing a zinc element, and the perovskite compound contains a halogen element.

### TECHNICAL FIELD

The present disclosure relates to a light-emitting element, a quantum-dot-containing composition, and a method for manufacturing the light-emitting element. The present application claims priority from Japanese Application JP2020-157235, filed on Sep. 18, 2020, the content of which is hereby incorporated by reference into this application.

### BACKGROUND ART

Solar cells that contain quantum dots as the material of a photoelectric conversion element have been studied, as disclosed in Non-Patent Literature 1 below. A method for manufacturing this solar cell includes substituting a halogenation element for the surface of lead sulfide (PbS). Accordingly, the surfaces of lead-sulfide quantum dots undergo halogenation and are then mixed into a lead perovskite precursor. The perovskite precursor with the quantum dots mixed is thereafter changed into an absorption layer of a photoelectric conversion element. This manufacture method enables a quantum dot covered with a compound having a perovskite crystal to be used for an absorption layer of a photoelectric conversion layer, thus improving the reliability of the photoelectric conversion element.

However, lead sulfide has a narrow band gap. Hence, a lead-sulfide quantum dot cannot emit visible light. Such a lead-sulfide quantum dot as disclosed in Non-Patent Literature 1 covered with a compound having a perovskite crystalline structure cannot be thus used as a material that emits visible light.

Under such circumstances, a light-emitting element includes a light-emitting layer that contains, as a material, a quantum dot covered with an organic compound called a ligand.

### CITATION LIST

### Non-Patent Literature

Non-Patent Literature: 1: Nature, 2019, 570, 96

### SUMMARY OF INVENTION

### Technical Problem

Upon current driving of such a light-emitting element as described above, the ligand gradually desorbs from the surface of the quantum dot. This causes a defect on the surface of the quantum dot. Accordingly, carriers, that is, electrons or holes, are trapped by an energy level established within the band gap by the defect. As a result, electric energy is converted into not light, but heat. This lowers light emission efficiency when the light-emitting element excites light.

Further, such a light-emitting element as described above has higher quantum-dot dispersibility within the light-emitting layer EML along with ligand increase, but hinders carrier injection into the quantum dots. This raises voltage for driving the light-emitting element. It is consequently difficult to improve the light emission efficiency.

To solve such a problem as described above, the present disclosure aims to provide a light-emitting element with improved emission efficiency of visible light, a quantum-dot-containing composition, and a method for manufacturing the light-emitting element.

### Solution to Problem

A light-emitting element according to one aspect of the present disclosure includes a light-emitting layer including the following: a quantum dot including a core having a surface exposed, or a quantum dot including the core and a shell covering the core; and a perovskite compound covering the quantum dot, wherein the surface of the core or the shell includes a semiconductor or an insulator containing a zinc element, and the perovskite compound contains a halogen element.

A quantum-dot-containing composition according to one aspect of the present disclosure includes the following: a quantum dot including a core having a surface containing a zinc element, or a quantum dot including a shell provided so as to cover the core, the shell including a semiconductor or an insulator containing a zinc element; and a perovskite precursor containing a solvent, a negative ion of a halogen element, and two kinds of combinations of univalent to trivalent positive ions.

A method for manufacturing a light-emitting element according to one aspect of the present disclosure includes the following steps: preparing a quantum-dot-dispersed solution containing a non-polar solvent and a quantum dot dispersed within the non-polar solvent; preparing a perovskite-precursor-dispersed solution containing a polar solvent and a perovskite precursor dispersed within the polar solvent; generating a mixed solution of the quantum-dot-dispersed solution and the perovskite-precursor-dispersed solution; applying the mixed solution or a processed solution with the mixed solution undergone a predetermined process onto a substrate; and burning the mixed solution or the processed solution on the substrate, wherein the quantum dot includes a core having a surface exposed or includes the core and a shell covering the core, the surface of the core or the shell includes a semiconductor or an insulator having a zinc element, and the perovskite precursor contains two kinds of halogenation metals.

### BRIEF DESCRIPTION OF DRAWINGS

FIG. 1 is a schematic sectional view of the structure of a light-emitting element according to a first embodiment.

FIG. 2 schematically illustrates the placement of the atoms of a perovskite compound according to the first embodiment.

FIG. 3 schematically illustrates the chemical structure of a light-emitting layer according to a comparative example.

FIG. 4 schematically illustrates the constituents of a quantum-dot-containing composition according to the first embodiment.

FIG. 5 illustrates Lewis acids that constitute the perovskite compound according to the first embodiment.

FIG. 6 is a graph showing the relationship between base hardness and a complex-formation equilibrium constant.

FIG. 7 schematically illustrates the light-emitting layer according to the comparative example near the interface between a quantum dot QD whose outermost layer is composed of a ZnS-containing shell and a solution containing a perovskite compound CsPbBr₃.

FIG. 8 is a photograph of a red-to-black converted mixture of a quantum dot having a ZnS shell and a lead perovskite precursor after their mixing in a process step for manufacturing the light-emitting layer according to the comparative example.

FIG. 9 illustrates the relationship between photo-luminescence quantum yield (PLQY) and the hardness of each metal ion serving as a Lewis acid.

FIG. 10 is a photograph of color changes in mixtures containing the metal ions shown in FIG. 9.

FIG. 11 is a graph showing the relationship between ion radius and tolerance factor.

FIG. 12 is a flowchart showing a method for manufacturing a light-emitting layer from the quantum-dot-containing composition according to the embodiment.

FIG. 13 illustrates the first step for the halogenation and combination of the quantum dots according to the embodiment.

FIG. 14 illustrates the second step for the halogenation and combination of the quantum dots according to the embodiment.

FIG. 15 illustrates the third step for the halogenation and combination of the quantum dots according to the embodiment.

FIG. 16 illustrates the fourth step for the halogenation and combination of the quantum dots according to the embodiment.

FIG. 17 illustrates the fifth step for the halogenation and combination of the quantum dots according to the embodiment.

FIG. 18 illustrates the sixth step for the halogenation and combination of the quantum dots according to the embodiment.

FIG. 19 illustrates the seventh step for the halogenation and combination of the quantum dots according to the embodiment.

FIG. 20 is a photograph of DMF, which is a polar solvent, and octane, which is a non-polar solvent, six hours later from their mixture in a process step of purifying the halogenated quantum dots according to the embodiment.

FIG. 21 is a photograph of DMF, which is a polar solvent, and octane, which is a non-polar solvent, 12 hours later from their mixture in the process step of purifying the halogenated quantum dots according to the embodiment.

FIG. 22 is a photograph of a mixture of 2 ml of DMF and 1 ml of toluene in the process step of purifying the halogenated quantum dots according to the embodiment.

FIG. 23 is a photograph of a mixture of 2 ml of DMF and a 6 ml of toluene in the process step of purifying the halogenated quantum dots according to the embodiment.

FIG. 24 illustrates whether the halogenated quantum dots dissolve or precipitate in a toluene-and-DMF mixed solution when the ratio of DMF to toluene is changed.

FIG. 25 schematically illustrates a perovskite precursor solution and a quantum dot being in contact together in a process step of combining the quantum dots and perovskite compounds according to the embodiment.

FIG. 26 schematically illustrates a perovskite compound crystal and a quantum dot being in contact together in the process step of combining the quantum dots and perovskite compound according to the embodiment.

FIG. 27 is a photograph of the light emission of the respective light-emitting layers according to an example and a comparative example with the quantum dots and perovskite compounds combined together.

FIG. 28 schematically illustrates constituents for improving the light emission efficiency of a quantum-dot-containing composition having ZnSe or ZnS shells.

FIG. 29 is a graph showing the relationship between the heating temperature and photo-luminescence quantum yield (PLQY) of the respective light-emitting layers of a first example, a first comparative example and a second comparative example.

FIG. 30 is a schematic sectional view of the structure of a light-emitting element according to a second embodiment.

FIG. 31 is a schematic sectional view of the structure of a light-emitting element according to a third embodiment.

### DESCRIPTION OF EMBODIMENTS

A light-emitting element, a quantum-dot-containing composition and a method for manufacturing the same according to the embodiments of the present disclosure will be described with reference to the drawings. It is noted that identical or equivalent components will be denoted by the same signs throughout the drawings, and the description of redundancies about the identical or equivalent components will not be repeated.

### First Embodiment

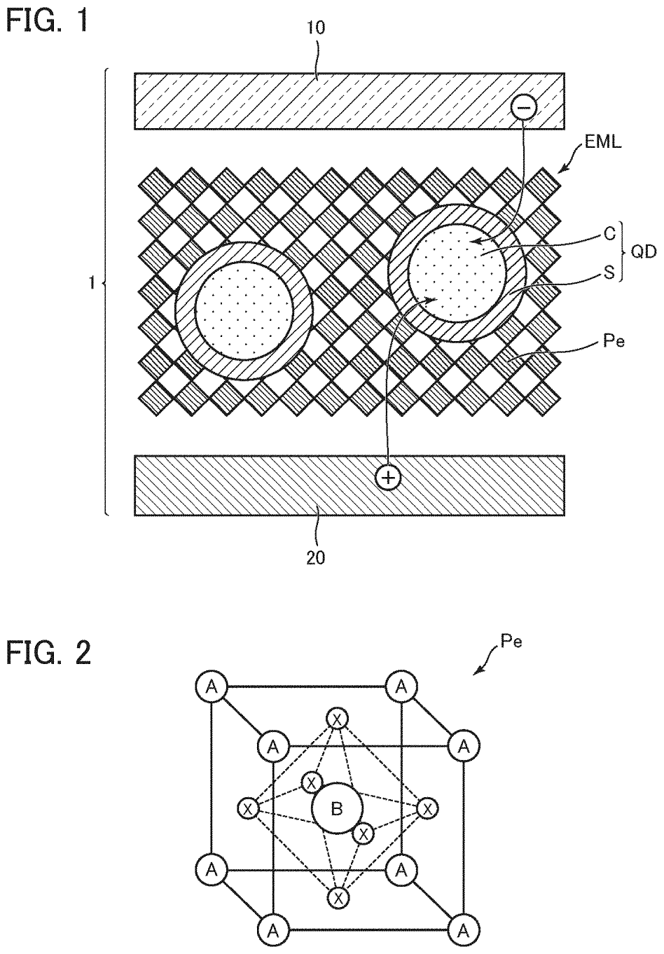

FIG. 1 is a schematic sectional view of the structure of a light-emitting element 1 according to a first embodiment. As illustrated in FIG. 1, the light-emitting element 1 includes an anode 10 and a cathode 20 disposed so as to face the anode 10. A light-emitting layer EML is disposed between the anode 10 and the cathode 20. The light-emitting layer EML includes quantum dots QD each including a core C and a shell S covering the core C.

It is noted that an electron transport layer (not shown) may be provided between the light-emitting layer EML and the anode 10, and that a hole transport layer (not shown) may be provided between the light-emitting layer EML and the cathode 20.

The principal component of the core C of the quantum dot QD may be a group II-VI semiconductor or group n-V semiconductor, a binary semiconductor, a ternary semiconductor, or a quaternary semiconductor or may be any semiconductor of, but not limited to, Cd, Se, Zn, Te, Ga, In, P or S that can be used as the core of a quantum dot.

The shell S includes a semiconductor or an insulator containing a zinc element. The principal component of the shell S of the quantum dot QD is made of a material, such as ZnS, ZnSe, ZnSSe, ZnTe or Zn₂₋ₓSiₓO₂ (0≤X≤1). Zinc silicate (Zn₂₋ₓSiₓO₂) is a semiconductor when x stands at 0.3 or smaller and is an insulator when x stands at 0.3 to 1.

However, the light-emitting layer EML may include the quantum dots QD each consisting of only the core C. The surface of the core C in this case needs to include a semiconductor or an insulator containing a zinc element. The principal component of the surface of the core C is made of a material, such as ZnS, ZnSe or ZnTe.

The quantum dots QD may have any particle diameter that falls within a range recognized as a quantum dot. The quantum dots QD thus may have any particle diameter that can achieve the following effect.

The quantum dots QD are used as a constituent of the light-emitting layer EML of a quantum light-emitting diode (QLED). However, the quantum dots QD may be used as a constituent of a wavelength converting layer.

When the quantum dots QD are used as a constituent of a wavelength converting layer, the quantum dots QD having different particle diameters involve different differences between the wavelength of light that is input to the wavelength converting layer and the wavelength of light that is output from the wavelength converting layer. This enables at least one of the wavelength of light not yet converted by the wavelength converting layer and the wavelength of light converted by the wavelength converting layer to be adjusted to a necessary value. A specific example of this wavelength converting layer will be detailed in a third embodiment.

The light-emitting layer EML according to this embodiment includes perovskite compounds covering the quantum dots QD. The perovskite compounds contain a halogen element.

To be more specific, the light-emitting element 1 according to this embodiment is configured such that each quantum dot QD containing Zn in its outermost layer is covered with a halogenation metal (chemical formula ABX₃) having a perovskite structure composed of Zn or an element X of a Lewis acid harder than Zn. As such, the quantum dot QD is covered with a halogenation metal (chemical formula ABX₃) containing no Pb. This can stabilize the quantum dot QD. It is noted that all of metals (elements A and B) constituting perovskite crystals contained in a perovskite compound Pe are preferably zinc or a Lewis acid harder than zinc.

This is because that a chemical reaction is less likely to occur at the interface between ZnS or ZnSe and the perovskite compound Pe if a metal identical to or harder than Zn of the shell S containing ZnS or ZnSe is used as an ingredient of the perovskite compound. It is noted that the perovskite compound Pe will be detailed later on.

The shell S may be anything containing a zinc element; in particular, the shell S preferably contains at least one of zinc sulfide and zinc selenide. This configuration improves the light emission efficiency of the light-emitting element 1 with more certainty. However, the shell S may be not only a semiconductor containing a zinc element, but also an insulator containing a zinc element.

Further, the shell S may be composed of, as other examples of the semiconductor or insulator containing a zinc element, a semiconductor or an insulator containing ZnS, ZnO, InP/ZnSe or CdS/ZnSe.

Further, the surface of the core C or the shell S may include, as other examples, a semiconductor or an insulator containing at least a zinc element and one or more elements selected from the group 16 elements. The group 16 elements are O, S, Se, Te, and Po.

Further, few of quantum dots containing PbS in their outermost layers emit visible light, as those in a comparative example described later on. However, the quantum dots QD according to this embodiment containing Zn in their outermost layers emit visible light.

The foregoing configuration of the light-emitting layer EML according to this embodiment can improve the light emission efficiency of the light-emitting element 1 that emits visible light. To be more specific, voltage necessary for driving the light-emitting element 1 lowers. Further, the endurance of the light-emitting element 1 enhances.

FIG. 2 schematically illustrates the placement of the atoms of the perovskite compound Pe according to the first embodiment. The perovskite compound Pe will be detailed with reference to FIG. 2.

As illustrated in FIG. 2, the perovskite compound Pe includes an element A placed at the corners of a cube, an element B positioned in the middle of the cube, and an element X positioned at intersection points of diagonal lines on planes of individual squares constituting the six faces of the cube. The perovskite compound Pe is expressed by the chemical formula ABX₃.

The element A in the chemical formula ABX₃ preferably contains at least one element selected from the group consisting of Na, K, Rb, Cs and La.

The element B in the chemical formula ABX₃ contains at least one element selected from the group consisting of Na, K, Mg, Ca, Sr, Ba, Y, Mn, Fe, Co, Ni, Cu, Zn, Al, Ga, In, Ge, Sn, As, Sb, Bi and lanthanoid. However, the element B is further preferably Zn. Lanthanoid is any of 15 elements consisting of La, Ce, Pr, Nd, Pm, Sm, Eu, Gd, Tb, Dy, Ho, Er, Tm, Yb and Lu.

The element X in the chemical formula ABX₃ preferably contains at least one element selected from the group consisting of F, Cl, Br and I. It is noted that negative ions of halogen elements such as F, Cl, Br, and I have the property of easily coordinating with Zn contained in the quantum dots QD.

Such a perovskite compound Pe as described above can improve the light emission efficiency of the light-emitting element 1 with more certainty.

To be more specific, the perovskite compound Pe further preferably includes at least one compound selected from the group consisting of CsZnF₃, CsZnCl₃, CsZnBr₃, CsZnI₃, RbZnF₃, RbZnCl₃, RbZnBr₃, RbZnI₃, CsZnFₓ₁Cl₃₋ₓ₁, CsZnClₓ₁Br₃₋ₓ₁, CsZnBrₓ₁I₃₋ₓ₁, RbZnFₓ₁C₃₋ₓ₁, RbZnClₓ₁Br₃₋ₓ₁ and RbZnBrₓ₁I₃₋ₓ₁, and the condition 0<X1<3 is further preferably satisfied. This configuration improves the light emission efficiency of the light-emitting element 1 with more certainty.

Although the perovskite compound Pe is CsMX₃ for instance, where M is a bivalent metal that is a Lewis acid as hard as or harder than zinc, a plurality of kinds of MM′ may be used instead of M. In this case, X is a halogen element, and M′ is a metal that is a Lewis acid different from M and as hard as or harder than zinc. The perovskite compound Pe may be thus, for instance, a double perovskite like Cs2MM′X₆.

Further, the perovskite compound Pe, when being a double perovskite, further preferably contains at least one compound selected from Cs₂NaYC₆, Cs₂NaBiCl₆, Cs₂NaInCl₆, Cs₂NaCeCl₆, Cs₂KYCl₆, Cs₂KBiCl₆, Cs₂KInCl₆, Cs₂NaCeCl₆, Cs₂Naₓ₂K₁₋ₓ₂YCl₆, Cs₂NaYₓ₂Ce₁₋ₓ₂Cl₆ and Cs₂Zmₓ₂Na₍₁₋ₓ₂₎Bi₍₁₋ₓ₂₎Cl₆, and the condition 0<X2<1 is further preferably satisfied. This configuration improves the light emission efficiency of the light-emitting element 1 with more certainty.

The light-emitting element 1 is preferably configured such that the weight ratio between the quantum dot QD and the perovskite compound Pe is a value that falls within a range of 1:100 to 10:1. This configuration further improves the light emission efficiency of the light-emitting element 1. This is because that if the weight ratio of the quantum dot QD to the perovskite compound Pe is smaller than 1/100, the probability of exciton generation within the quantum dot QD reduces, and that if the weight ratio of the quantum dot QD to the perovskite compound Pe is larger than 10, the number of quantum dots QD that are not covered with the perovskite compound Pe increases.

The quantum dots QD are preferably disposed dispersedly within a group of crystals of the perovskite compounds Pe. This configuration also further improves the light emission efficiency of the light-emitting element 1.

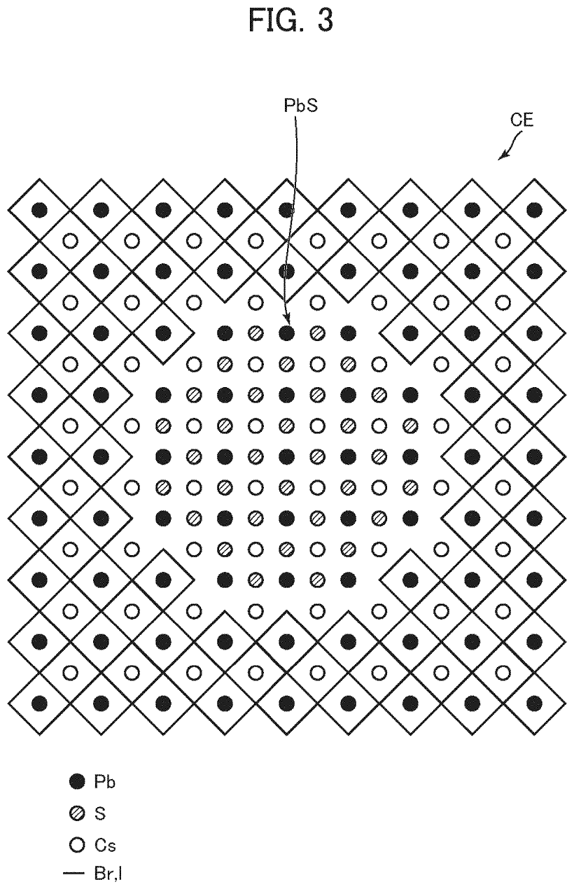

FIG. 3 schematically illustrates the chemical structure of a light-emitting layer CE according to a comparative example. The light-emitting layer CE according to the comparative example includes black lead sulfide (PbS) quantum dots and halogenation-lead perovskite compounds covering the lead sulfide quantum dots. Such a perovskite compound of the light-emitting layer according to the comparative example has such a chemical structure as CsPbBrₓI₃₋ₓ, and 0<x<3 is established. The quantum dots according to the comparative example containing PbS in their outermost layers do not emit visible light. In contrast, the quantum dots QD according to this embodiment, containing Zn in their outermost layers, emit visible light.

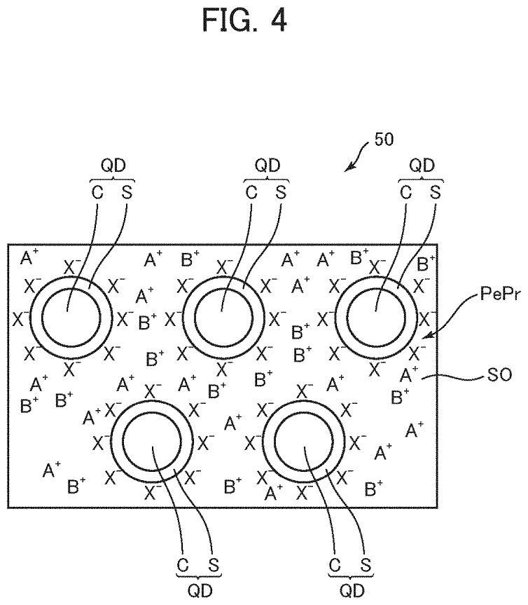

FIG. 4 schematically illustrates the constituents of a quantum-dot-containing composition 50 according to the first embodiment. The constituents of the quantum-dot-containing composition 50 in the present disclosure will be described with reference to FIG. 4.

The quantum-dot-containing composition 50 includes the quantum dots QD and perovskite precursors PePr. Each quantum dot QD includes the shell S provided so as to cover the core C and including a semiconductor or an insulator containing a zinc element. The perovskite precursors PePr are ion crystals and contain a solvent SO, negative ions X⁻ of a halogen element and two kinds of combinations of univalent to trivalent positive ions.

The quantum dots QD are preferably dispersed within the solvent SO. The halogen-element negative ions X⁻ preferably attach to the surface of the shell S.

The two kinds of combinations of univalent to trivalent positive ions preferably include any one of three combinations listed below.

The first combination is a combination of a first positive ion A⁺ of univalence and a second positive ion B⁺ of trivalence.

The second combination is a combination of a first positive ion A⁺ of trivalence and a second positive ion B⁺ of univalence.

The third combination is a combination of a first positive ion A⁺ of bivalence and a second positive ion B⁺ of bivalence.

The shell S preferably contains at least one of zinc sulfide (ZnS) and zinc selenide (ZnSe).

The two kinds of positive ions A⁺ and B⁺ are positive ions different from each other and are provided with three conditions (1) to (3) listed below.

(1) Each of the two kinds of positive ions exists stably in univalent, bivalent or trivalent form.

(2) Each of the two kinds of positive ions in the form of a Lewis acid is as hard as or harder than zinc. As such, the quantum dot QD and the perovskite compound Pe do not react chemically.

(3) The two kinds of positive ions A⁺ and B⁺ and the halogen negative ions X⁻ can constitute a perovskite crystalline structure.

The light-emitting layer EML is formed from the foregoing quantum-dot-containing composition 50.

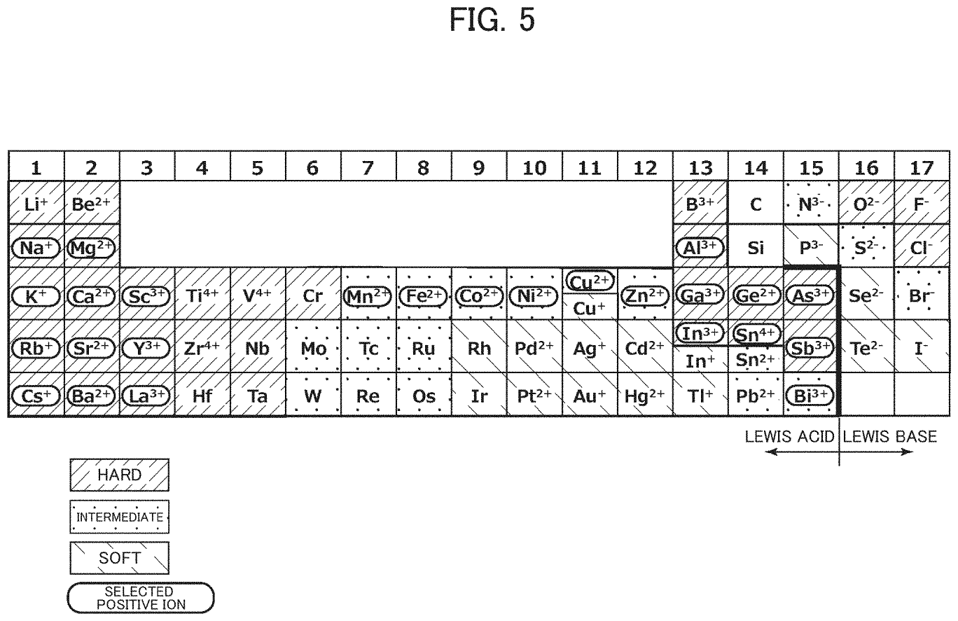

FIG. 5 illustrates Lewis acids that constitute the perovskite compounds Pe according to the first embodiment.

As seen from FIG. 5, the positive ions A⁺ or positive ions B provided with the above three conditions (1) to (3) are ions encircled by ovals. That is, the positive ions A⁺ or positive ions B⁺ are any of Na⁺, Mg²⁺, Al³⁺, K⁺, Ca²⁺, Sc³⁺, Mn²⁺, Fe²⁺, Co²⁺, Ni²⁺, Cu²⁺, Zn²⁺, Ga³⁺, Ge²⁺ As³⁺, Rb⁺, Sr²⁺, Y³⁺, In³⁺, Sn²⁺, Sb³⁺, Cs⁺, Ba²⁺, Bi³⁺ and La³⁺.

The reason why the positive ions A⁺ and the positive ions B⁺ are selected as a candidate is that mixing a quantum dot having ZnS or ZnSe in its outermost layer into the perovskite precursor PePr containing positive ions other than the foregoing positive ions causes a chemical reaction due to these positive ions. That is, the reason is that a mixture of a quantum dot having ZnS or ZnSe in its outermost layer and of a perovskite compound containing positive ions other than the positive ions provided with the foregoing three conditions (1) to (3) is not stable chemically.

In view of the foregoing, the first positive ions A⁺ according to this embodiment preferably include at least one positive ion selected from the group consisting of Na⁺, K⁺, Rb⁺, Cs⁺, Mg²⁺, Ca²⁺, Sr²⁺, Ba²⁺, Y³⁺ and La³⁺. Further, the second positive ions B⁺ preferably include at least one positive ion selected from the group consisting of Mn²⁺, Fe²⁺, Co²⁺, Ni²⁺, Cu²⁺, Zn²⁺, Al³⁺, Ga³⁺, In³⁺, Ge²⁺, Sn²⁺, As³⁺, Sb³⁺ and Bi³⁺.

Further, since the perovskite compound Pe and the Zn shell S are a favorable combination, the B-site in the chemical formula ABX₃ of the perovskite compound Pe preferably has Zn negative ions. As such, the second positive ions B⁺ are Zn²⁺ in this embodiment. It is noted that the negative ions X⁻ preferably include at least one negative ion selected from the group consisting of F⁻, Cl⁻, Br⁻ and I⁻.

According to the hard and soft acids and bases (HSAB) principle, a hard base and a hard acid form a compound easily, and a soft base and a soft acid form a compound easily. Zinc is a somewhat hard Lewis acid, and sulfur and selenium are somewhat soft Lewis bases. Sulfur or selenium and a somewhat soft metal thus form a compound easily. As a result, the shell S containing sulfur or selenium is eroded. Consequently, the endurance of the shell S containing sulfur or selenium conceivably lowers. As such, a semiconductor or an insulator having the perovskite compound Pe is desirably made of zinc that is used for the shell S of the quantum dot QD or is desirably made of a metal kind that is a harder Lewis acid than zinc.

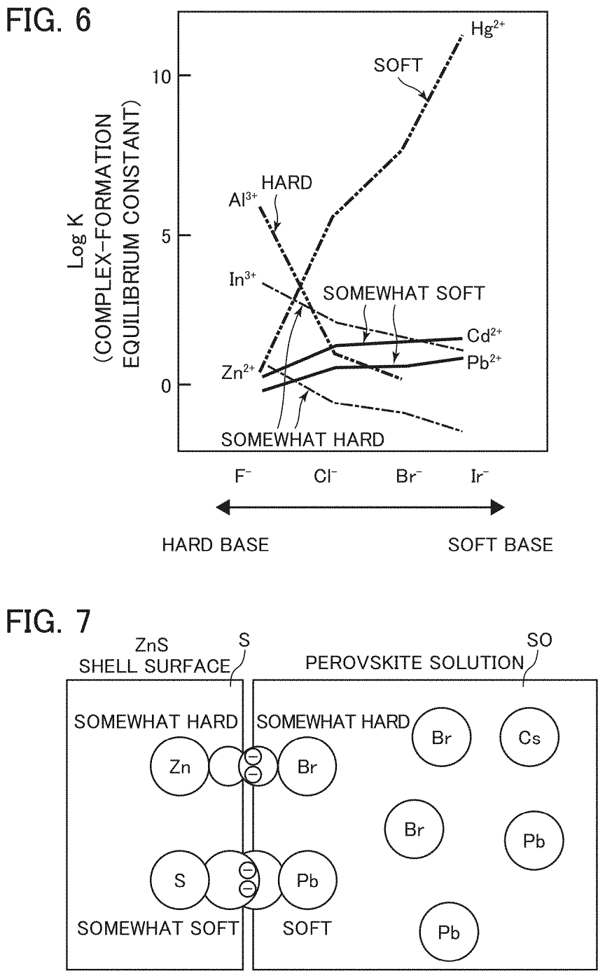

FIG. 6 is a graph showing the relationship between base hardness and a complex-formation equilibrium constant. FIG. 6 reveals that a hard acid and a hard base easily react chemically, and that a soft acid and a soft base easily react chemically. FIG. 7 schematically illustrates the vicinity of the interface between the quantum dot QD having the ZnS-containing shell S in its outermost layer and a perovskite compound CsPbBr₃. FIG. 7 shows that Zn, which is a somewhat hard acid, and Br, which is a somewhat hard base, easily react chemically at the interface between the ZnS shell and the perovskite precursor, and that Pb, which is a somewhat soft acid, and S, which is a soft base, easily react chemically at the interface between the ZnS shell and the perovskite precursor.

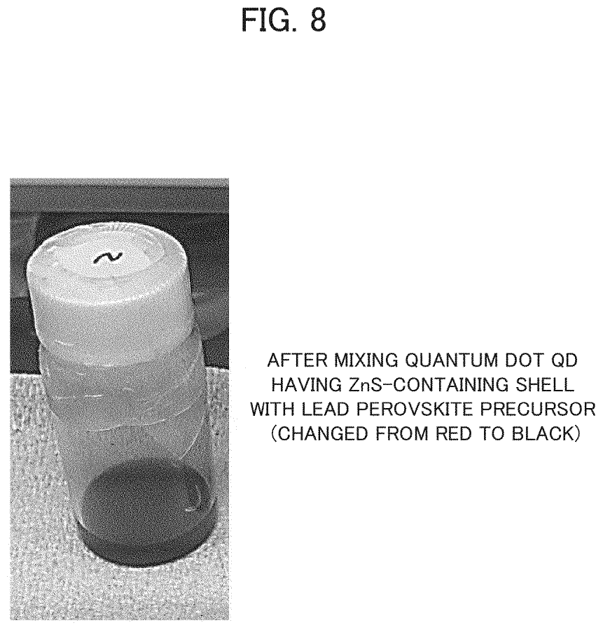

FIG. 8 is a photograph of a mixture of a quantum dot having a ZnS-containing shell and a lead perovskite precursor according to a comparative example that has been converted into red to black by the foregoing chemical reaction after their mixing. As seen from FIG. 8, the quantum-dot-containing composition according to the comparative example changes color from red to black. Forming the light-emitting layer EML by using this quantum-dot-containing composition undergone color change into black does not offer favorable light emission efficiency.

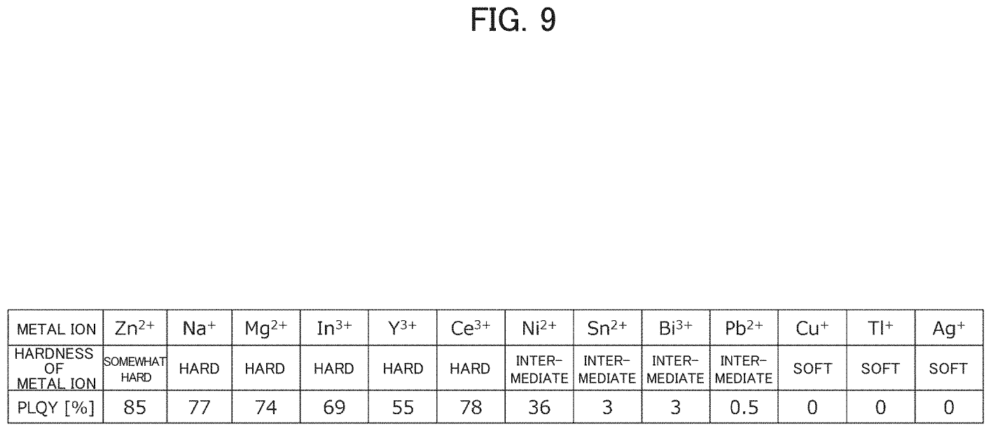

FIG. 9 illustrates the relationship between photo-luminescence quantum yield (PLQY) and the hardness of each metal ion serving as a Lewis acid. The PLQYs in FIG. 9 are values measured 12 hours later from mixture of the quantum dot QD having the ZnS-containing shell S in its outermost layer and of zinc acetate, sodium acetate, magnesium acetate, indium acetate (III), cerium acetate, acetate nickel, tin acetate (II), lead acetate (II), bismuth acetate, copper acetate (I), thallium acetate (I) or silver acetate (I). The PLQY does not lower greatly even when a quantum dot and a hard metal ion are mixed together.

However, the PLQY lowers when the quantum dot QD having the ZnS-containing shell S in its outermost layer and a metal ion having intermediate hardness are mixed together. Further, a mixture of the quantum dot QD having the ZnS-containing shell S in its outermost layer and a soft metal ion emits light little.

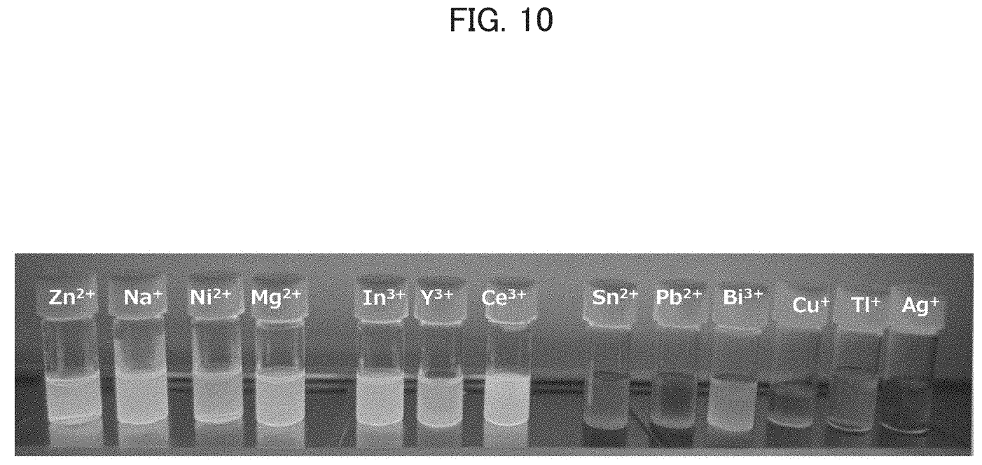

FIG. 10 is a photograph of color changes in the metal ions shown in FIG. 9.

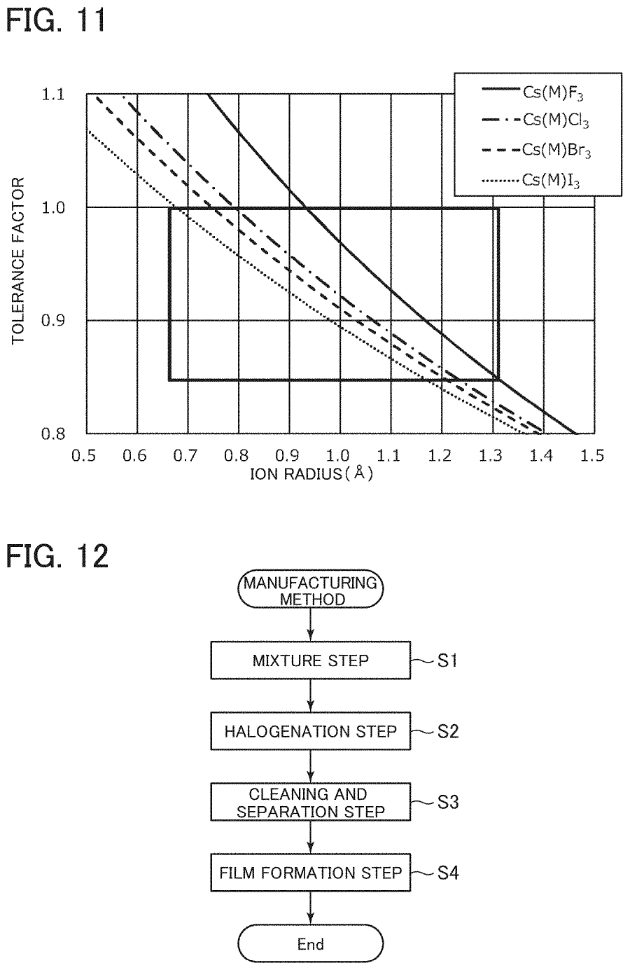

FIG. 11 is a graph showing the relationship between ion radius and tolerance factor. As illustrated in FIG. 11, for a perovskite crystal structure to be formed, the tolerance factor, t, expressed by Expression 1 below desirably stands at a value of 8.5 to 1.0 and more desirably stands at a value closer to 1.0, so that a stable cubic structure is obtained.

Tolerance Factor t

$$\begin{matrix} & t = \frac{{r}_{A} + {r}_{x}}{\sqrt{2} ( {r}_{B} + {r}_{x} )} \\ {r}_{A} : ion radius of A - site cation & ( Rb , Cs , etc . ) \\ {r}_{A} : Ion radius of B - site cation & ( Pb , Zn , etc . ) \\ {r}_{X} : ion radius of X - site anion & ( F , Cl , Br , I )\end{matrix} \qquad [ Expression 1 ]$$

To be specific, when the ion radius of cesium, which is herein an A-site cation, stands at a value ranging from 1.30 to 0.68 Å, the quantum dot QD and any of the halogens constitute a perovskite crystal. To be specific, when the ion radius of rubidium, which is herein an A-site cation, stands at a value ranging from 1.16 to 0.58 Å, the quantum dot QD and any of the halogens constitute a perovskite crystal. For instance, CsZnBr₃ made of zinc having an ion radius of 0.88 Å has a tolerance factor t of 0.95. It is thus estimated that an ideal perovskite crystal is formed in a perovskite compound CsZnBr₃.

In the quantum-dot-containing composition 50, a combination of the foregoing first positive ions A⁺, second positive ions B⁺ and negative ions X⁻ is preferably a combination that generates a crystal of at least one perovskite compound Pe selected from the group consisting of CsZnF₃, CsZnCl₃, CsZnBr₃, CsZnI₃, RbZnF₃, RbZnC₃, RbZnBr₃, RbZnI₃, CsZnFₓ₁C₃₋ₓ₁, CsZnClₓ₁Br₃₋ₓ₁, CsZnBrₓ₁I₃₋ₓ₁, RbZnFₓ₁C₃₋ₓ₁, RbZnClₓ₁Br₃₋ₓ₁ and RbZnBrₓ₁I₃₋ₓ₁, where 0<X1<3 is satisfied.

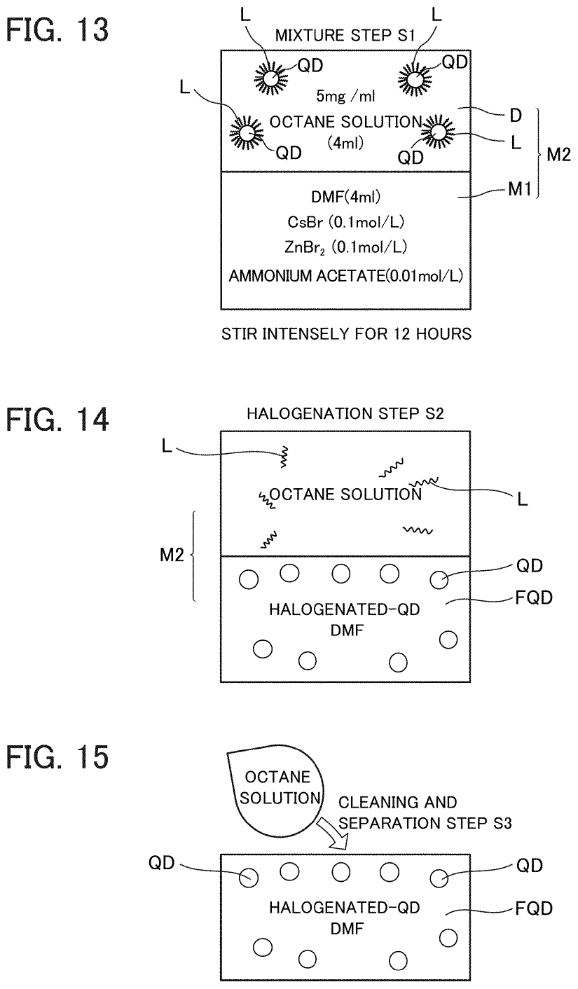

FIG. 12 is a flowchart showing a method for manufacturing the light-emitting layer EML from the quantum-dot-containing composition 50 according to this embodiment. FIG. 13 to FIG. 19 illustrate the first to seventh steps for the halogenation and combination of the quantum dots according to the embodiment. The following describes the method for manufacturing the light-emitting layer EML according to this embodiment with reference to FIG. 12 to FIG. 19.

As illustrated in FIG. 12, the method for manufacturing the light-emitting layer EML roughly includes four process steps: a mixture step S1, a halogenation step S2, a cleaning and separation step S3, and a film formation step S4.

The mixture step S1 shown in FIG. 12 is preparing the perovskite precursor PePr. To be specific, the mixture step S1 is mixing together a solution containing a halogenation substance of the foregoing element A and a solution containing a halogenation substance of the foregoing element B. This obtains a first mixed solution M1 illustrated in FIG. 13. At this time, an organic acid, such as ammonium acid, an inorganic salt, such as sodium chloride, or other things may be added to a mixed solvent in order to adjust the solubility of the first mixed solution M1 or to cause catalysis within the first mixed solution M1.

To be specific, the mixture step S1 is performed under a nitrogen atmosphere in the following procedure.

In the mixture step S1, firstly, cesium bromide (CsBr), zinc bromide (ZnBr₂), and ammonium acetate are dissolved into 4 ml of N,N-dimethylformamide (DMF) solvent. That is, the halogenation substance of the element A is cesium bromide (CsBr), and the halogenation substance of the element B is zinc bromide (ZnBr₂). Accordingly, a DMF solution is generated. Cesium bromide (CsBr) and zinc bromide (ZnBr₂) are an example of two kinds of halogenation metals, which will be described later on. The DMF solvent is an example polar solvent. The generated DMF solution is the first mixed solution M1. The first mixed solution M1 contains Zn²⁺, Cs⁺, and Br⁻.

In the first mixed solution M1, the concentration of cesium bromide with respect to the DMF solution, the concentration of zinc bromide with respect to the DMF solution, and the concentration of ammonium acetate with respect to the DMF solution all stand at 0.01 mol/L.

The next is preparing 4 ml of octane solution containing the quantum dots QD having an organic modified base at 5 mg/ml in concentration. This octane solvent is an example first non-polar solvent.

The halogenation step S2 in FIG. 12 is mixing, firstly, the dispersed solution D containing the quantum dots QD and the foregoing first mixed solution M1 together, as illustrated in FIG. 13. This generates a second mixed solution M2. A commercially available solution can be used as the dispersed solution D containing the quantum dots QD. The dispersed solution D containing the quantum dots QD contains such ligands as organic molecules L coordinating with the quantum dots QD. The second mixed solution M2 is stirred thereafter.

To be specific, the halogenation step S2 is performed under a nitrogen atmosphere in the following procedure.

In the halogenation step S2, 4 ml of octane solution containing the quantum dots QD having an organic modified base at 5 mg/ml in concentration, that is, the dispersed solution D, and a DMF solution containing Zn²⁺, Cs⁺ and Br⁻, that is, the first mixed solution M1, are mixed together. This generates the second mixed solution M2. In the second mixed solution M2, the first mixed solution M1, which is on the lower side, and the dispersed solution D, which is on the upper side, are separated into two layers, as illustrated in FIG. 13. The second mixed solution M2 in this state is stirred intensely for 12 hours.

Accordingly, the organic molecules L coordinating with the quantum dots QD disengage from the quantum dots QD and remain in the dispersed solution D, as illustrated in FIG. 14. In contrast, the quantum dots QD with the organic molecules L disengaged therefrom move into the first mixed solution M1. The surfaces of the quantum dots QD undergo halogenation within the DFM solution by such action.

To be specific, the quantum dots QD within the dispersed solution D on the upper side move to the DMF solution on the lower side, which is the first mixed solution M1. The next is discarding the octane solution on the upper side, where the ligands L remain, but no quantum dots QD remain, after confirming that almost all of the quantum dots QD have completely moved to the DMF solution. Accordingly, a solution FQD having the halogenated quantum dots QD and the DMF solvent remains.

In the second mixed solution M2, the octane solvent of the original dispersed solution D with the quantum dots QD dispersed, and the DMF solvent covered with the perovskite compounds Pe and containing the halogenated quantum dots QD are separated into two layers, as illustrated in FIG. 14.

The next, i.e., the cleaning and separation step S3, is easily removing a supernatant liquid (octane solvent) containing no quantum dots QD from the second mixed solution M2, as illustrated in FIG. 15. To be specific, 4 ml of octane solvent is mixed into the solution FQD, and this mixed solution is stirred to clean the solution FQD. The octane used for the cleaning is discarded thereafter. The next is dropping 2 ml of toluene, which is an example second non-polar solvent, onto the solution FQD. The solution FQD is centrifuged thereafter.

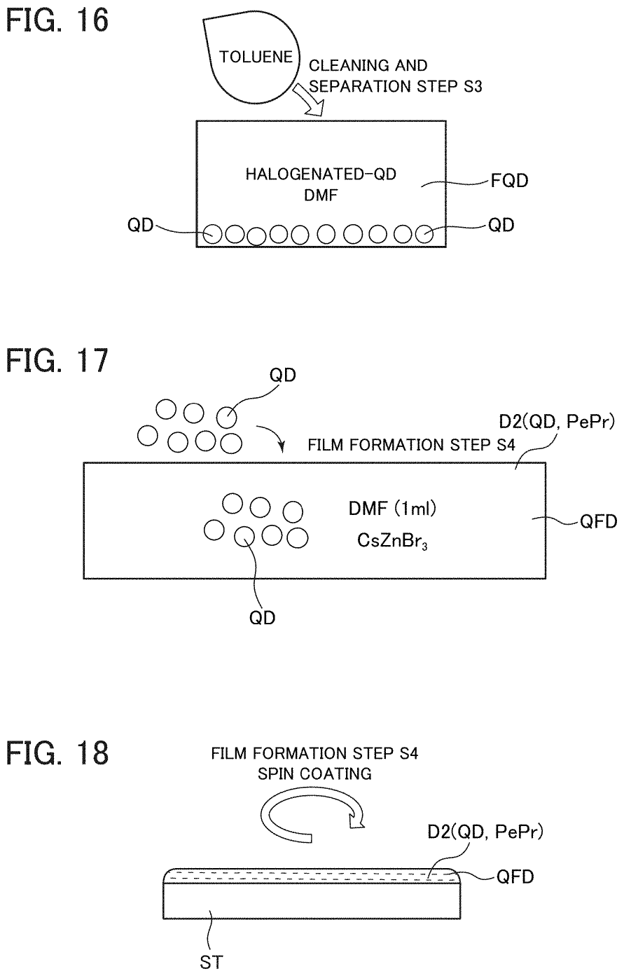

Accordingly, zinc perovskite crystals, to be specific, the quantum dots QD covered with the perovskite compounds Pe and halogenated precipitate within the solution FQD, as illustrated in FIG. 16. The zinc perovskite crystals and the solution FQD are separated thereafter. The quantum dots QD are precipitated within the separated solution FQD by further adding 10 ml of toluene to the separated solution FQD. The solution FQD with the quantum dots QD precipitating is centrifuged thereafter.

The next, i.e., the film formation step S4, is dispersing a mixture of the precipitated CsZnBr₃ crystals and quantum dots QD into 1 ml of DMF solvent, as illustrated in FIG. 17. This generates a dispersed solution D2. The dispersed solution D2 is the solution FQD containing precursor ions of CsZnBr₃ and 1 ml of DMF solvent and is the perovskite precursor PePr containing the halogenated quantums QD. The next is applying the dispersed solution D2 containing the quantum dots QD onto a substrate ST, as illustrated in FIG. 18. The substrate ST is thereafter rotated to spin-coat the dispersed solution D2 onto the substrate ST.

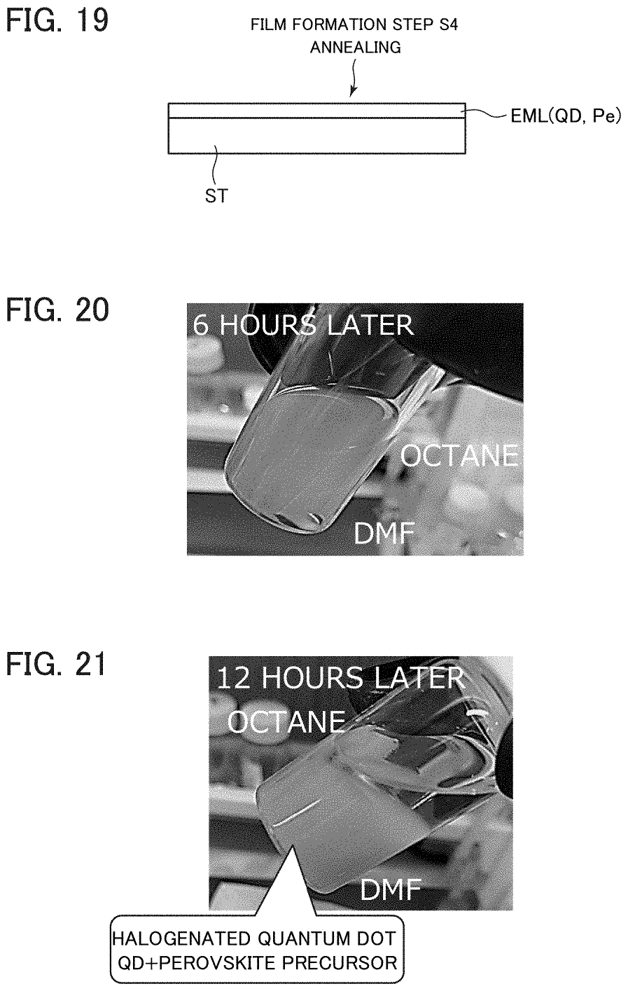

As illustrated in FIG. 19, the dispersed solution D2 on the substrate ST containing the quantum dots QD, that is, the perovskite precursor PePr containing the halogenated quantum dots QD undergo annealing to vaporize moisture from the dispersed solution D2. This forms the light-emitting layer EML including the perovskite compounds Pe containing the quantum dots QD onto the substrate ST, as illustrated in FIG. 19.

The following is a summary of the method for manufacturing the light-emitting element through the foregoing formation according to this embodiment.

As illustrated in FIG. 12 to FIG. 19, the first process step in this embodiment is preparing the dispersed solution D, which is an example quantum-dot-dispersed solution, containing the octane solvent, which is an example first non-polar solvent, and the quantum dots QD dispersed in the octane solvent.

The quantum dots QD that are used in the method for manufacturing the light-emitting element 1 according to this embodiment each include the core C having a surface exposed or each include the core C and the shell S covering the core C. The surface of the core C or the shell S includes a semiconductor or an insulator having a zinc element. The perovskite precursors PePr include two kinds of halogenation metals. The two kinds of halogenation metals will be detailed later on.

The next is preparing the first mixed solution M1, which is an example perovskite-precursor-dispersed solution, containing the DMF solvent, which is an example polar solvent, and the perovskite precursor PePr dispersed within the DMF solvent. The second mixed solution M2, which is an example mixed solution of the dispersed solution D and the first mixed solution M1, is generated.

Accordingly, the quantum dots QD within the dispersed solution D move to the first mixed solution M1 after the second mixed solution M2 is generated. The quantum dots QD are thereafter halogenated by the two kinds of halogenation metals within the mixed solution M1. The second mixed solution M2 is consequently turned into the solution FQD containing the halogenated quantum dots QD.

Thereafter, a processed solution with the second mixed solution M2 undergone a predetermined process is applied onto the substrate ST. The processed solution on the substrate ST undergoes burning.

The following describes the foregoing predetermined process and the foregoing processed solution.

The predetermined process includes a step of stirring the second mixed solution M2 for more than six hours, for 12 hours for instance, after generating the second mixed solution M2. This relatively long time stirring increases the possibility that the quantum dots QD come into contact with the two kinds of halogenation metals, thereby enabling the halogenated quantum dots QD to be generated at a high rate.

The octane solvent, which is an unnecessary non-polar solvent, is removed from the second mixed solution M2 after the foregoing stir step and before the foregoing step of applying the processed solution onto the substrate ST. This can generate the second mixed solution M2 containing the quantum dots QD and containing no octane solvent.

The forgoing predetermined process also includes a step of adding, after the step of removing the octane solvent, toluene, which is an example second non-polar solvent, to the solution FQD containing the halogenated quantum dots QD and the DMF solvent with the octane solvent removed from the second mixed solution M2. The solution FQD with toluene added thereto is centrifuged before the step of applying the processed solution, which is the solution FQD, onto the substrate ST.

The foregoing two kinds of halogenation metals are a combination that generates the perovskite compounds Pe incorporating the quantum dots QD through the step of burning the foregoing processed solution, which is the solution FQD. The perovskite compounds Pe include at least one compound selected from the group consisting of CsZnF₃, CsZnCl₃, CsZnBr₃, CsZnI₃, RbZnF₃, RbZnC₃, RbZnBr₃, RbZnI₃, CsZnFₓ₁Cl₃₋ₓ₁, CsZnClₓ₁Br₃₋ₓ₁, CsZnBrₓ₁I₃₋ₓ₁, RbZnFₓ₁C₃₋ₓ₁, RbZnClₓ₁Br₃₋ₓ₁ and RbZnBrₓ₁I₃₋ₓ₁, and the condition 0<X1<3 is satisfied.

FIG. 20 is a photograph of DMF, which is a polar solvent, and octane, which is a first non-polar solvent, six hours later from their mixture in a process step of purifying the halogenated quantum dots QD according to this embodiment. FIG. 21 is a photograph of DMF, which is a polar solvent, and octane, which is a first non-polar solvent, 12 hours later from their mixture in the process step of purifying the halogenated quantum dots QD according to this embodiment. As seen from the comparison between FIG. 20 and FIG. 21, the separation of DMF, which is a polar solvent, and octane, which is a first non-polar solvent, progresses along with time.

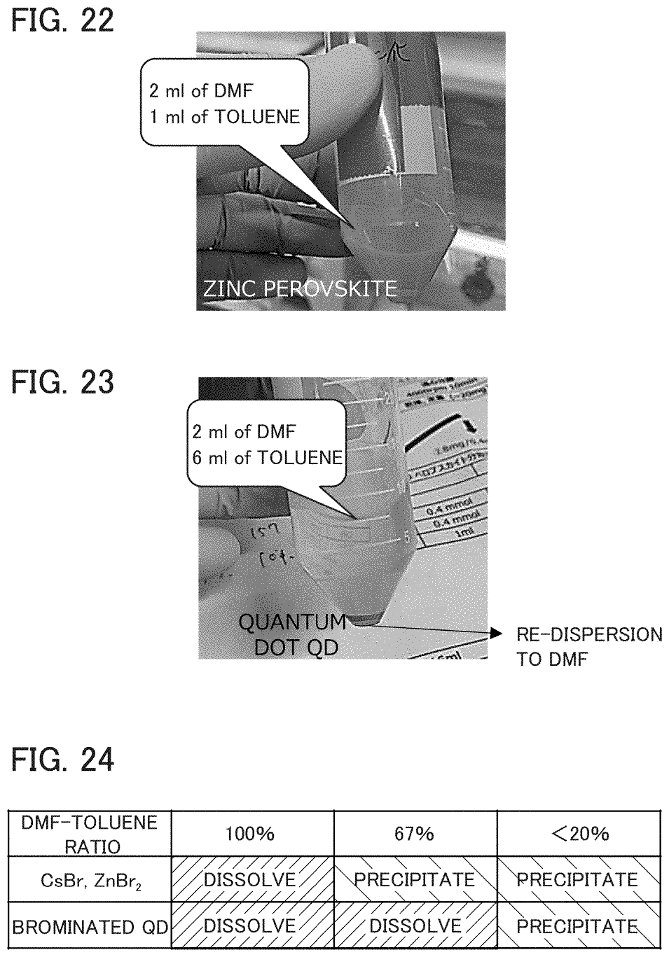

FIG. 22 is a photograph of a mixture of 2 ml of DMF and 1 ml of toluene, which is an example second non-polar solvent, in the process step of purifying the halogenated quantum dots QD according to this embodiment. FIG. 23 is a photograph of a mixture of 2 ml of DMF and 6 ml of toluene in the process step of purifying the halogenated quantum dots QD according to this embodiment. As seen from the comparison between FIG. 22 and FIG. 23, the separation of DMF, which is a polar solvent, and octane, which is a first non-polar solvent, progresses along with increase in the amount of toluene, which is an example second polar solvent.

FIG. 24 illustrates whether the halogenated quantum dots QD dissolve or precipitate in a toluene-and-DMF mixed solution when the ratio of DMF to toluene, which is an example second non-polar solvent, is changed. As seen from FIG. 24, the halogenated quantum dots QD and the perovskite precursor PePr can be separated by using the difference in the solubility of the halogenated quantum dots QD with respect to the mixed solution of toluene, which is an example second non-polar solvent, and DMF.

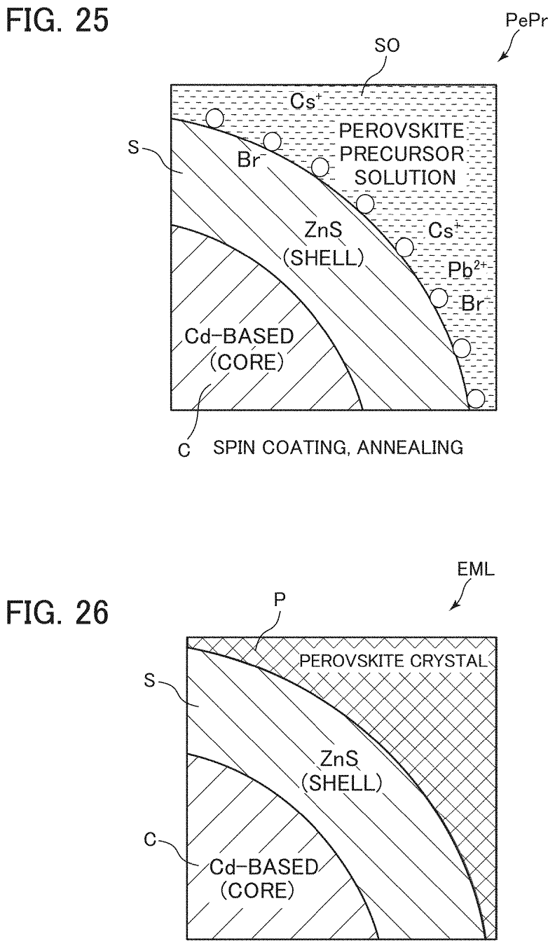

FIG. 25 schematically illustrates a solution of the perovskite precursor PePr and the quantum dot QD being in contact together in a process step of combining the quantum dots QD and perovskite compounds Pe according to this embodiment. FIG. 26 schematically illustrates a crystal of the perovskite compound Pe and the quantum dot QD being in contact together in the process step of combining the quantum dots QD and perovskite compounds Pe according to this embodiment.

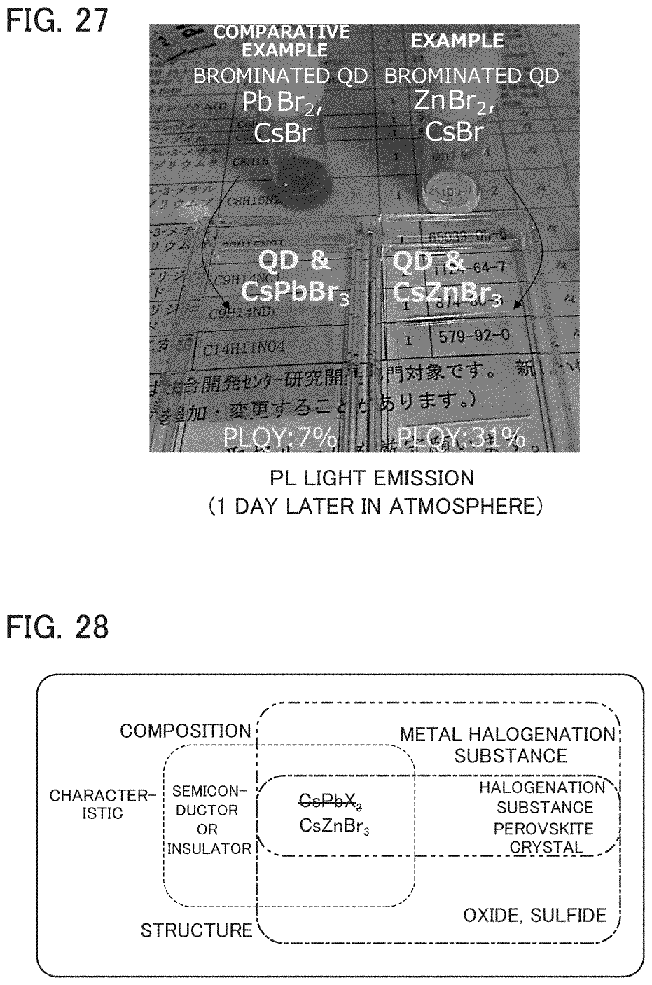

FIG. 27 is a photograph of the light emission of the respective light-emitting layers EML according to an example and a comparative example with the quantum dot and perovskite compound Pe combined together. As seen from FIG. 27, the light emission of the light-emitting layer EML with the combined quantum dot QD and perovskite compound Pe according to the example is more favorable than the light emission of the light-emitting layer EML with the combined quantum dot QD and perovskite compound Pe according to the comparative example.

FIG. 28 schematically illustrates constituents for improving the light emission efficiency of the quantum-dot-containing composition 50 having ZnSe or ZnS shells. As seen from FIG. 28, the quantum-dot-containing composition 50 according to this embodiment includes a dispersing medium for the quantum dots QD having ZnSe or ZnS in their shells.

The quantum dots QD are semiconductors. The quantum dots QD exist within the dispersing medium with their surfaces halogenated. The Lewis acid of the metal ions within the dispersing medium is as hard as or harder than Zn. A perovskite compound, which is a dispersing medium, has a band gap equal to or larger than that of the quantum dots QD. Thus for instance, CsPbX₃ does not fall under the quantum dots QD according to this embodiment, whereas CsZnBr₃ falls under the perovskite compounds according to this embodiment.

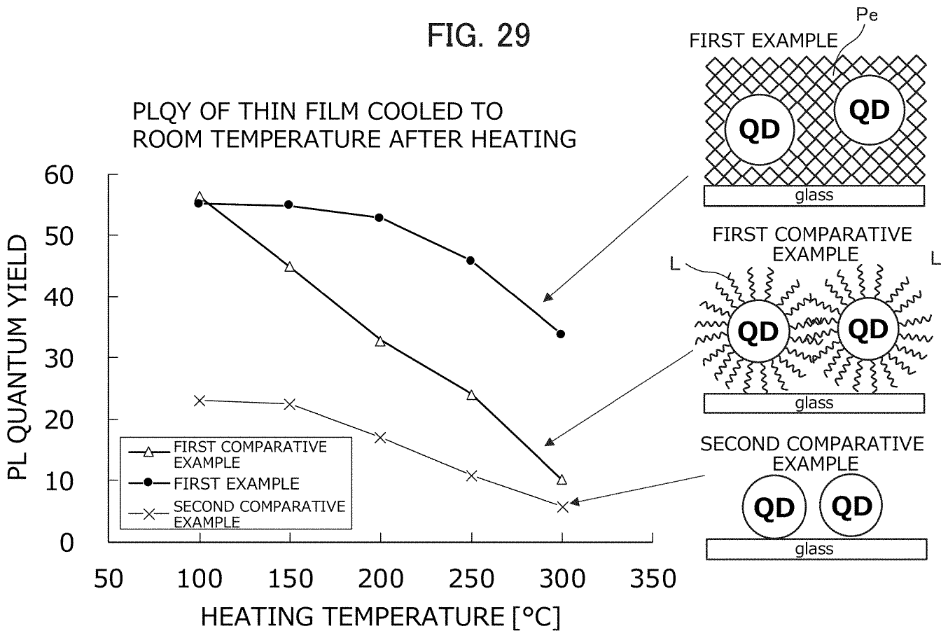

FIG. 29 is a graph showing the relationship between the heating temperature and photo-luminescence quantum yield (PLQY) of the respective light-emitting layers of a first example, a first comparative example and a second comparative example.

To obtain the results shown in FIG. 29, the first example was conducted, where CsBr and ZnBr₂ were dissolved into a solvent of DMSO:DMF=4:1 to generate a primary mixed solution of CsBr and ZnBr₂ having a ratio of 0.4 mol/l with respect to the solvent. The quantum dots QD with their surfaces brominated were mixed into the primary mixed solution in such a manner that the ratio of these surface-brominated quantum dots QD to CsZnBr₃ contained in the primary mixed solution stood at 30 wt %, to thus generate a secondary mixed solution. The secondary mixed solution underwent spin coating onto a glass substrate, followed by heating under atmosphere with a hotplate to generate a light-emitting layer. Then, the PL quantum yield of the light-emitting layer was measured.

In contrast, the first comparative example was conducted, where the quantum dots QD in the first example with their surfaces not yet brominated, that is, the quantum dots QD modified by octanethiol, were applied onto a glass substrate and were heated. The second comparative example was conducted, where the quantum dots QD used in the first example with their surfaces brominated were applied onto a glass substrate and were heated.

A third comparative example not shown was conducted, where a primary mixed solution was generated in such a manner that the ratio of CsBr and PbBr₂ to a solvent stood at 0.4 mol/L. The quantum dots QD with their surfaces brominated were mixed into the primary mixed solution to generate a secondary mixed solution. The secondary mixed solution was applied onto a glass substrate and was heated. It was noted that the PLQY in the comparative example 3 was 7%.

### Second Embodiment

The following describes a light-emitting element, a quantum-dot-containing composition and a method for manufacturing the light-emitting element according to a second embodiment. It is noted that the description of points similar to those in the first embodiment will not be repeated. The light-emitting element according to this embodiment is different from the light-emitting element according to the first embodiment in the following regard.

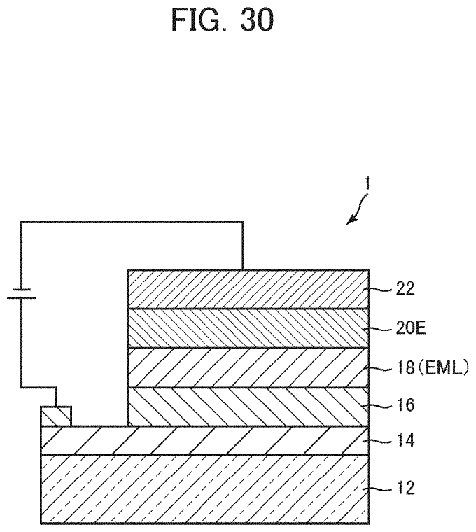

FIG. 30 is a schematic sectional view of the structure of the light-emitting element according to the second embodiment.

As illustrated in FIG. 30, the light-emitting element 1 according to this embodiment is configured such that an anode 14, a hole transport layer 16, a light-emitting layer 18 containing the quantum dots QD, an electron transport layer 20E, and a cathode 22 are stacked in this order on a substrate 12. The quantum dots QD are those described in the first embodiment. The anode 14 and the cathode 22 are coupled to an external power source so as to inject carriers into the light-emitting layer 18.

The light-emitting layer 18 according to this embodiment corresponds to the light-emitting layer EML according to the first embodiment. That is, the quantum-dot-containing composition 50 according to the first embodiment is used as raw materials for manufacturing the light-emitting layer 18 according to this embodiment. The light-emitting element 1 according to this embodiment improves the light emission efficiency of visible light.

### Third Embodiment

The following describes a light-emitting element, a quantum-dot-containing composition and a method for manufacturing the light-emitting element according to a third embodiment. It is noted that the description of points similar to those in the first embodiment will not be repeated. The light-emitting element according to this embodiment is different from the light-emitting element according to the first embodiment in the following regard.

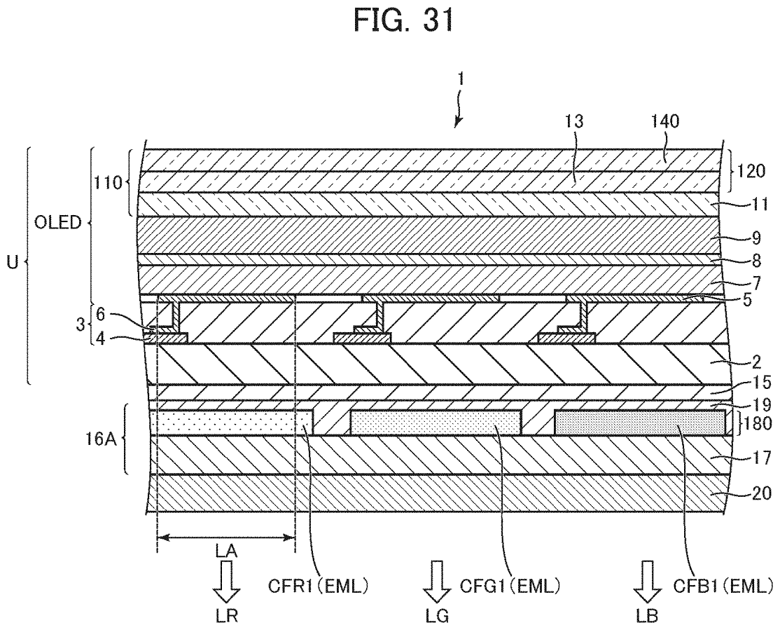

FIG. 31 is a schematic sectional view of the structure of the light-emitting element according to the third embodiment.

The light-emitting element 1 illustrated in FIG. 31 includes the following on a base 2: a TFT unit 3 having routed electrodes 6 and TFTs 4; and an organic EL unit U composed of an organic EL element (OLED).

The OLED is provided on the TFT unit 3. The OLED includes three first electrodes 5 in locations corresponding to respective color filters of three colors, which will be described later on. On the three first electrodes are three light-emitting layers 7. The light-emitting layers 7 emit white light.

On the light-emitting layers 7 is a second electrode 8. Furthermore, on the second electrode 8 is a sealing structure where a first sealing layer 9 and a second sealing layer 110 are stacked in this order. The second sealing layer 110 has a first adhesive layer 11, and an alpet 120 composed of a protective film 140 and aluminum foil 13.

In the OLED, a region consisting of the first electrodes 5, light-emitting layers 7 and second electrode 8 constitutes a light emission area LA.

A color filter unit 16A is disposed on a surface of the base 2 opposite to the surface where the OLED is disposed, with the second adhesive layer 15 interposed therebetween. The color filter unit 16A is configured such that a color filter layer 180 where a red color filter CFR1, a green color filter CFG1, and a blue color filter CFB1 are spaced from each other is disposed on a second base 17. The red color filter CFR1 contains a red coloring agent. The green color filter CFG1 contains a green coloring agent. The blue color filter CFB1 contains a blue coloring agent.

On the color filter layer 180 is a flattening layer 19, which is joined to the back surface of the first base 2 with the second adhesive layer 15 interposed therebetween. A polarizing plate is disposed outside the color filter unit 16A.

The light-emitting element 1 is configured such that the organic EL element is designed as a white-light emission type, and that white light passes through the individual color filters, thus taking out light LR that emits red, light LG that emits green, and light LB that emits blue in a bottom-emission form. Each of the color filters CFR1, CFG1 and CFB1 according to this embodiment is a wavelength converting layer and corresponds to the light-emitting layer EML according to the first embodiment. The quantum-dot-containing composition 50 according to the first embodiment is used as raw materials for manufacturing each of the color filters CFR1, CFG1 and CFB1.

The light-emitting element 1 according to this embodiment includes the light-emitting layers 7 as a light source corresponding to the light-emitting layer EML according to the first embodiment. Further in this embodiment, each of the color filters CFR1, CFG1 and CFB1, corresponding to the light-emitting layer EML, is formed as a wavelength converting layer disposed in a location closer to the light taking surface of the light-emitting element 1 than the light-emitting layers 7, serving as a light source. The light-emitting element 1 according to this embodiment improves the light emission efficiency of visible light.

Further, although the light-emitting element 1 according to this embodiment is a white-light-emitting organic EL element by way of example, the color of light emission in the light-emitting layers 7 is not limited to white; the light-emitting layers 7 may emit blue light. For instance, the light-emitting element 1 may be replaced with a blue-light-emitting organic electroluminescence (EL) element. When the light-emitting element 1 is a blue-light-emitting organic EL, the blue color filter CFB1 may be omitted. Furthermore, the light-emitting element 1 is not limited to an organic EL element; the light-emitting element 1 may be a micro light-emitting diode (LED).

1. A light-emitting element comprising a light-emitting layer including
a quantum dot including a core having a surface exposed, or a quantum dot including the core and a shell covering the core, and
a perovskite compound covering the quantum dot,
wherein the surface of the core or the shell includes a semiconductor or an insulator containing a zinc element, and
the perovskite compound contains a halogen element, wherein
the perovskite compound includes a compound that is expressed by a chemical formula ABX₃,
an element A in the chemical formula includes at least one element selected from the group consisting of Na, K, Rb, Cs and La,
an element B in the chemical formula includes at least one element selected from the group consisting of Na, K, Mg, Ca, Sr, Ba, Y, Mn, Fe, Co, Ni, Cu, Zn, Al, Ga, In, Ge, Sn, As, Sb, Bi and lanthanoid,
an element X in the chemical formula includes at least one element selected from the group consisting of F, Cl, Br and I, and
the element B includes Zn.

2. The light-emitting element according to claim 1, wherein the surface of the core or the shell includes a semiconductor or an insulator containing at least a zinc element and one or more elements selected from group 16 elements.

3. The light-emitting element according to claim 1, wherein the surface of the core or the shell contains at least one kind selected from the group consisting of ZnS, ZnSe, ZnSSe, ZnTe, ZnSTe, ZnSeTe and Zn₂₋ₓSiₓO₂, where 0≤X≤1 is satisfied.

4-5. (canceled)

6. The light-emitting element according to claim 1, wherein the perovskite compound includes at least one compound selected from the group consisting of CsZnF₃, CsZnCl₃, CsZnBr₃, CsZnI₃, RbZnF₃, RbZnCl₃, RbZnBr₃, RbZnI₃, CsZnFₓ₁Cl₃₋ₓ₁, CsZnClₓ₁Br₃₋ₓ₁, CsZnBrₓ₁I₃₋ₓ₁, RbZnFₓ₁Cl₃₋ₓ₁, RbZnClₓ₁Br₃₋ₓ₁, and RbZnBrₓ₁I₃₋ₓ₁, where 0<X1<3 is satisfied.

7. (canceled)

8. The light-emitting element according to claim 1, further comprising:
an anode; and
a cathode disposed to face the anode,
wherein the light-emitting layer is provided between the anode and the cathode.

9. The light-emitting element according to claim 1, further comprising a light source,
wherein the light-emitting layer is formed as a wavelength converting layer disposed in a location closer to a light taking surface of the light-emitting element than the light source.

10. The light-emitting element according to claim 1, wherein a weight ratio between the quantum dot and the perovskite compound is a value that falls within a range of 1:100 to 10:1.

11. The light-emitting element according to claim 1, wherein the quantum dot is disposed dispersedly within a group of crystals of the perovskite compound.

12. A quantum-dot-containing composition comprising:
a quantum dot including a core having a surface containing a zinc element, or a quantum dot including a shell provided so as to cover the core, the shell including a semiconductor or an insulator containing a zinc element; and
a perovskite precursor containing a solvent, a negative ion of a halogen element, and at least two kinds of combinations of univalent to trivalent positive ions, wherein
the two kinds of combinations of univalent to trivalent positive ions include at least any one of a first combination of a first positive ion of univalence and a second positive ion of trivalence, a second combination of a first positive ion of trivalence and a second positive ion of univalence, and a third combination of a first positive ion of bivalence and a second positive ion of bivalence,
the first positive ion includes at least one positive ion selected from the group consisting of Na⁺, K⁺, Rb⁺, Cs⁺, Mg²⁺, Ca²⁺, Sr²⁺, Ba²⁺, Y³⁺ and La³⁺,
the second positive ion includes at least one positive ion selected from the group consisting of Mn²⁺, Fe²⁺, Co²⁺, Ni²⁺, Cu²⁺, Zn²⁺, Al³⁺, Ga³⁺, In³⁺, Ge²⁺, Sn²⁺, As³⁺, Sb³⁺ and Bi³⁺, the negative ion includes at least one negative ion selected from the group consisting of F⁻, Cl⁻, Br⁻ and I⁻, and
the second positive ion is Zn²⁺.

13. The quantum-dot-containing composition according to claim 12, wherein the quantum dot is dispersed within the solvent.

14. The quantum-dot-containing composition according to claim 12, wherein the negative ion of the halogen element attaches to a surface of the shell.

15-18. (canceled)

19. The quantum-dot-containing composition according to claim 12, wherein the surface of the core or the shell includes a semiconductor or an insulator containing at least a zinc element and one or more elements selected from group 16 elements.

20. The quantum-dot-containing composition according to claim 12, wherein the surface of the core or the shell contains at least one kind selected from the group consisting of ZnS, ZnSe, ZnSSe, ZnTe, ZnSTe, ZnSeTe and Zn₂₋ₓSiₓO₂, where 0≤X≤1 is satisfied.

21-24. (canceled)

25. A light-emitting element comprising a light-emitting layer including
a quantum dot including a core having a surface exposed, or a quantum dot including the core and a shell covering the core, and
a perovskite compound covering the quantum dot,
wherein the surface of the core or the shell includes a semiconductor or an insulator containing a zinc element, and
the perovskite compound contains a halogen element, wherein
the perovskite compound includes a compound that is expressed by a chemical formula ABX₃,
an element A in the chemical formula includes at least one element selected from the group consisting of Na, K, Rb, Cs and La,
an element B in the chemical formula includes at least one element selected from the group consisting of Na, K, Mg, Ca, Sr, Ba, Y, Mn, Fe, Co, Ni, Cu, Zn, Al, Ga, In, Ge, Sn, As, Sb, Bi and lanthanoid, and
an element X in the chemical formula includes at least one element selected from the group consisting of F, Cl, Br and I, and
the perovskite compound includes at least one compound selected from the group consisting of Cs₂NaYCl₆, Cs₂NaBiCl₆, Cs₂NaInCl₆, Cs₂NaCeCl₆, Cs₂NaYₓ₂Ce₁₋ₓ₂ Cl₆, Cs₂Naₓ₂K₁₋ₓ₂YCl₆ and Cs₂Znₓ₂Na₍₁₋ₓ₂₎Bi₍₁₋ₓ₂₎Cl₆, where 0<X2<1 is satisfied.

26. The light-emitting element according to claim 25, wherein the surface of the core or the shell includes a semiconductor or an insulator containing at least a zinc element and one or more elements selected from group 16 elements.

27. The light-emitting element according to claim 25, wherein the surface of the core or the shell contains at least one kind selected from the group consisting of ZnS, ZnSe, ZnSSe, ZnTe, ZnSTe, ZnSeTe and Zn₂₋ₓSiₓO₂, where 0≤X≤1 is satisfied.

28. The light-emitting element according to claim 25, further comprising:
an anode; and
a cathode disposed to face the anode,
wherein the light-emitting layer is provided between the anode and the cathode.

29. The light-emitting element according to claim 25, further comprising a light source,
wherein the light-emitting layer is formed as a wavelength converting layer disposed in a location closer to a light taking surface of the light-emitting element than the light source.

30. The light-emitting element according to claim 25, wherein a weight ratio between the quantum dot and the perovskite compound is a value that falls within a range of 1:100 to 10:1.

31. The light-emitting element according to claim 25, wherein the quantum dot is disposed dispersedly within a group of crystals of the perovskite compound.
